(19) United States
(12) Patent Application Publication
(10) Pub. No.: US 2011/0132002 A1
(43) Pub. Date: Jun. 9, 2011

(54) CORE-SHELL NANOWIRE WITH UNEVEN STRUCTURE AND THERMOELECTRIC DEVICE USING THE SAME

(75) Inventors: Eun-kyung LEE, Yongin-si (KR); Byoung-lyong CHOI, Yongin-si (KR); Dongmok WHANG, Seoul (KR); Sang-jin LEE, Yongin-si (KR); Jong-woon LEE, Busan (KR)

(73) Assignee: SAMSUNG ELECTRONICS CO., LTD, Suwon-si (KR)

(21) Appl. No.: 12/957,075

(22) Filed: Nov. 30, 2010

(30) Foreign Application Priority Data
Dec. 8, 2009 (KR) 10-2009-0121409

(51) Int. Cl. F25B 21/02; H01L 35/32; H01L 35/34

(52) U.S. Cl. 62/3.7; 257/9; 438/478

(57) ABSTRACT

A core-shell nanowire with an uneven surface structure can be advantageously used in thermoelectric devices. The core-shell nanowire with the uneven surface structure includes a core region and a shell region, wherein the uneven surface structure is formed in the shell region.

### CROSS-REFERENCE TO RELATED APPLICATIONS

This application claims priority to Korean Patent Application No. 10-2009-0121409, filed on Dec. 8, 2009, and all the benefits accruing therefrom under 35 U.S.C. §119, the content of which in its entirety is herein incorporated by reference.

### BACKGROUND

1. Field

The present disclosure relates to core-shell nanowires with uneven surface structures and to thermoelectric devices using the same.

2. Description of the Related Art

Unlike bulk materials, a nanowire has a relatively large surface area with respect to its volume, and thus nanowires may be used in a variety of different applications. Nanowires are therefore widely researched especially in fields pertaining to optical nano devices, that include the use of lasers and electrical nano devices, such as transistors, memories, nanosensors, and the like.

In general, a nanowire has uniform surface characteristics and may be fabricated to have any of various diameters, and its physical and electrical characteristics may be changed based upon its surface characteristics. A nanowire may be formed of any of various materials, such as silicon, tin oxides, gallium nitride, carbon, or the like. Currently, it is possible to adjust the length and the thickness of a nanowire by varying experimental or manufacturing parameters.

A general nanowire synthesizing method is a vapor-liquid-solid (VLS) growth method in which a nanowire may be grown by forming and melting an alloy of a nanowire material in the presence of a metal catalyst. The nanowire material is extracted from between the melted liquid alloy and a solid substrate.

### SUMMARY

Provided herein are core-shell nanowires with uneven surface structures and thermoelectric devices or cooling devices using the core-shell nanowires.

Additional aspects will be set forth in part in the description which follows and, in part, will be apparent from the description, or may be learned by practice of the presented embodiments.

According to one aspect of the present invention, a core-shell nanowire has an uneven surface structure, where the core-shell nanowire includes a core region and a shell region and where the uneven surface structure is formed in the shell region.

The uneven surface structure may include a plurality of pores formed on a surface of and inside the shell region, or a plurality of protrusions protruding from the surface of the shell region.

The core-region or the shell region may be formed of a semiconductor of the family of group IV, semiconductor of the family of group III-V, semiconductor of the family of group II-VI, oxide semiconductors, nitride semiconductors, or a group VI family atom and at least one of a group IV family atom and a group V family atom.

In another aspect of the invention, the core region may include a p-type impurity or an n-type impurity.

According to another aspect of the present invention, a method of fabricating a core-shell nanowire that has an uneven surface structure includes attaching nanoparticles to a surface of the shell region; forming an oxide material on the surface of the shell region by oxidizing the surface of the shell region; and forming the uneven surface structure by removing the oxide material and the nanoparticles.

The nanoparticles may be formed of a metal exhibiting higher electronegativity when compared with a material that is used in the shell region.

The shell region may be formed of silicon, and the nanoparticles may be formed of silver (Ag), gold (Au), platinum (Pt), or copper (Cu).

The shell region may be formed of silicon, and the nanowire may include an uneven surface structure oxidized by using hydrogen peroxide (H₂O₂), potassium chromate (K₂Cr₂O₇), or potassium permanganate (KMnO₄).

In the attaching of the nanoparticles to the surface of the shell region, the nanoparticles may be formed on the surface of the shell region by dipping the nanowire in a solution in which a metal precursor and a fluoric acid are mixed.

The attaching of the nanoparticles to the surface of the shell region may include removing an oxide layer from the surface of the shell region and attaching nanoparticles to the surface of the shell region; where the nanoparticles are formed of a material that forms a compound with a material constituting the shell region.

The shell region may be oxidized through a wet oxidization process using H₂O gas or a dry oxidization process using O₂ gas at a temperature of about 600° C. to about 1,100° C.

A portion oxidized through the wet oxidization process or the dry oxidization process may be removed through an etching process, and the nanoparticles may also be removed through the etching process.

The shell region may be formed of silicon, and the nanoparticles may form metal silicide together with the material constituting the shell region.

According to another aspect of the present invention, a thermoelectric device or a cooling device employing a nanowire with an uneven surface structure, the nanowire including a core region and a shell region, wherein the uneven surface structure is formed in the shell region.

### BRIEF DESCRIPTION OF THE DRAWINGS

The above and other aspects, advantages and features of this disclosure will become more apparent by describing in further detail exemplary embodiments thereof with reference to the accompanying drawings, in which:

FIG. 1 is a diagram of a core-shell nanowire with an uneven surface structure according to an embodiment of the present invention;

FIGS. 2A and 2B are diagrams depicting an embodiment in which the uneven surface structure is a porous structure and an embodiment in which the uneven surface structure is a protruding structure, respectively;

FIG. 3 is a scanning electron microscopic (SEM) image of a nanowire with an uneven surface structure formed on the surface of the shell region; and

FIGS. 4A through 4C are diagrams showing a thermoelectric device employing a core-shell nanowire with an uneven surface structure.

### DETAILED DESCRIPTION

Reference will now be made in detail to embodiments, examples of which are illustrated in the accompanying drawings, wherein like reference numerals refer to the like elements throughout. In this regard, the present embodiments may have different forms and should not be construed as being limited to the descriptions set forth herein. Accordingly, the embodiments are merely described below, by referring to the figures, to explain aspects of the present description.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

[The above paragraph may be replaced with the following] Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

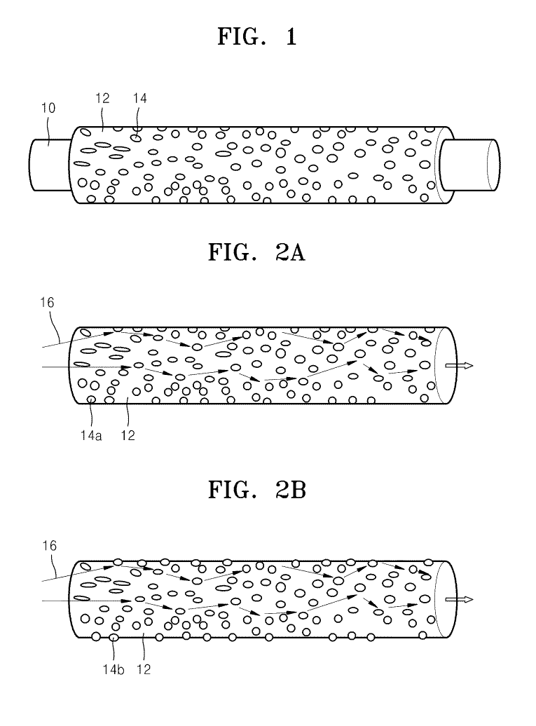

FIG. 1 is a diagram of a core-shell nanowire with an uneven surface structure according to an embodiment of the present invention.

Referring to FIG. 1, the core-shell nanowire with an uneven surface structure according to the present embodiment includes a core region 10, a shell region 12, and an uneven surface structure 14 formed in the shell region 12. Here, the uneven surface structure 14 may partly be a porous region formed in a surface of the shell region 12 toward the core region 10. In one embodiment, the uneven surface structure may protrude outwards from the surface of the shell region 12. In another embodiment, the uneven surface structure may encompass pores as well as protrusions that are disposed on the surface of the shell region 12.

FIGS. 2A and 2B are diagrams showing a case in which the uneven surface structure is a porous structure and a case in which the uneven surface structure is a protruding structure, respectively. In the FIGS. 2A and 2B, only the shell region 12 of the nanowire is shown. Referring to FIG. 2A, pores 14a are formed in the shell region 12. Referring to FIG. 2B, protrusions 14b are formed on the surface of the shell region 12. The shell region 12 may have an increased surface area by forming such uneven surface structures, and, for example, the thermoelectric characteristic of the shell region 12 may be significantly increased as phonon scattering increases.

Here, the core region 10 or the shell region 12 of the nanowire may be formed of various materials. For example, the core region 10 or the shell region 12 of the nanowire may be formed from the semiconductor family of group IV, the semiconductor family of groups III-V, the semiconductor family of groups II-VI, oxide semiconductors, nitride semiconductors, or group VI family atoms and at least one of group IV family atoms and group V family atoms. Here, examples of the semiconductor family of group IV may include Si, Ge, and SiC, examples of the semiconductor family of group III-V may include GaN, GaAs, and AsP, and examples of the semiconductor family of group II-VI may include CdSe, CdS, and ZnS. Furthermore, examples of the oxide semiconductors may include ZnO, and examples of the nitride semiconductors may include silicon nitride or germanium nitride. However, embodiments of the present invention are not limited thereto. Furthermore, the core region 10 may be doped with a p-type impurity or an n-type impurity to exhibit electric conductivity significantly different from that of the shell region 12. The length of the nanowire including the core region 10 and the shell region 12 may be from about several nanometers (“nm”) to about several centimetres (“cm”).

The pores or protrusions 14a shown in FIG. 2A may have any of various cross-sectional shapes, where the cross-section is measured perpendicular to the longitudinal axis of the pore or the protrusion. Examples of cross-sectional shapes are circular, elliptical, polygonal, tapered, or conical. The pores or protrusions may have combinations of such shapes. Diameters of the pores 14a may be from about 0.1 nm to about several micrometers (“μm”). However, the present invention is not limited thereto.

Hereinafter, a method of fabricating a core-shell nanowire with an uneven surface structure according to an embodiment of the present invention will be described.

In a method of fabricating a core-shell nanowire with an uneven surface structure, nanoparticles are attached to a shell region of a core-shell nanowire, the surface of the shell region is oxidized through an oxidization process, and an oxide layer formed in the shell region and the nanoparticles are removed through an etching process. Thus, pores may be formed inside the shell region or on the surface of the shell region.

Methods of fabricating a nanowire will be described in an example below. First, a substrate is prepared, and a catalyst material layer is formed thereon. The catalyst material may be a metal, such as Au, Ni, Ag, Al, Fe, or the like. Then, a nanowire may be grown on the catalyst material layer by supplying SiH₄ gas, for example, thereto as a Si source gas. Here, a core-shell nanowire, in which a core region is formed of silicon (Si) and a shell region is formed of silica (SiO₂), may be provided by then supplying O₂ gas to the outer surface of the silicon. However, the present invention is not limited thereto, and a nanowire may be fabricated by using any of various methods.

A method of forming pores in a shell region will now be described. Nanoparticles are attached to the surface of a shell region of a nanowire. Here, the nanoparticles may be formed of a metal exhibiting greater electronegativity than the nanowire in order to selectively oxidize the nanowire during the oxidization process. For example, if the nanowire is formed of silicon, the nanoparticles may be formed of Ag, Au, Pu, or Cu. However, the present invention is not limited thereto. Then, when the shell region of the nanowire is oxidized by using an oxidizing agent, an oxide layer is formed on the surface of the shell region, and thus the nanoparticles permeate into the shell region. If the shell region is formed of silicon, the oxidizing agent may be an agent that induces the oxidization of silicon such as H₂O₂, K₂Cr₂O₇, KMnO₄, or the like. However, the present invention is not limited thereto, and any of various oxidizing agents may be used according to a raw material constituting the shell region. Then, when the oxide layer and the nanoparticles are removed from the surface of the shell region, pores are formed where the nanoparticles were. If the shell region is formed of silicon, the oxide layer may be removed by using a hydrofluoric acid solution. Here, shapes and sizes of cross-sections of the pores may vary based on shapes and sizes of the nanoparticles attached to the surface of the shell region. Furthermore, depths of the pores from the surface of the shell region may be controlled by controlling the total time period used for the oxidization and for the etching processes.

Instead of directly attaching nanoparticles to the surface of the shell region, nanoparticles may also be affixed to a the surface that lies below the surface of the shell region. This is achieved by using a metal precursor, as will be described below.

For example, if the shell region is formed of silicon, when the nanowire is dipped in a solution in which silver nitrate (AgNO₃) and a fluoric acid material are mixed, and an electroless deposition process is performed, Ag nanoparticles are formed on the surface of the shell region. If the nanowires with the silver nanoparticles disposed thereon is now subjected to an oxidizing agent, the surface of the nanowire is oxidized to form a layer of silica and the nanoparticles are now embedded in the silica shell. Then, when the oxidized region of the surface of the shell region and the nanoparticles on the surface of the shell region are removed, pores may be formed on the surface of and inside the shell region as described above.

The process described above may be performed at room temperature and in the oxidization process or the etching process, an oxidizing agent or an etching material may be selected based on materials that are used to form the nanowire. A process of forming pores in a nanowire through an oxidization process using an oxidizing gas at a high temperature will be described below.

After the oxide layer, (which is either naturally formed (by exposure to air or oxygen) or formed via a chemical reaction) on the surface of the nanowire 10, is removed by using a fluoric acid, a wet oxidization process using H₂O gas or a dry oxidization process using O₂ gas may be performed at a temperature of about 600° C. to about 1,100° C., for example. It is easier to form an uneven surface structure on the surface of the shell region via a dry oxidization process since oxidization is slower in the dry oxidization process. The nanoparticles may include the material of the shell. For example, if the shell region of the nanowire is formed of silicon, the nanoparticles may be formed of a material capable of forming a metal silicide. Examples of such materials are metals such as Au, Ni, Co, or the like. In a high-temperature oxidization process, if the nanoparticles are formed of Au, oxidized materials are formed in portions of the surface of the shell region on which the nanoparticles are not formed, and a metal silicide grows into the nanowire from portions of the surface of the shell region on which the nanoparticles are formed. Since the growth rate of the metal silicide is faster than the rate of formation of the oxide layer, the metal silicide is formed deeper inside the shell region than the thickness of the oxide layer. When the oxide material and the metal silicide are removed, portions in which the metal silicide was formed become deep pores.

Through the process as described above, pores may be formed on the surface of the shell region and inside the shell region, and, as more time is taken for the processes, such as the oxidization process, the depth of the pores may increase.

In cases of forming protrusions on the surface of the shell region, a natural oxide layer formed on the surface of the shell region is first etched and removed. Nanoparticles are then attached to the surface of the shell region. Then, an oxidizing gas is supplied at a temperature of about 600° C. to about 1,100° C. to oxidize the surface of the shell region. A new oxide layer is formed into the shell region 12 in portions of the surface of the shell region exposed between nanoparticles. An oxide material is also formed below the nanoparticles. When this oxide layer on the surface of the shell region is removed via an etching process, portions of the surface of the shell region on which the nanoparticles exist protrude, and the other portions of the surface of the shell region from which the natural oxide layer is removed are sunken. After the oxide layer is removed, the nanoparticles are etched and removed. Here, the portions from which the nanoparticles are removed are relatively more protruded as compared to the portions from which the oxide layer is removed.

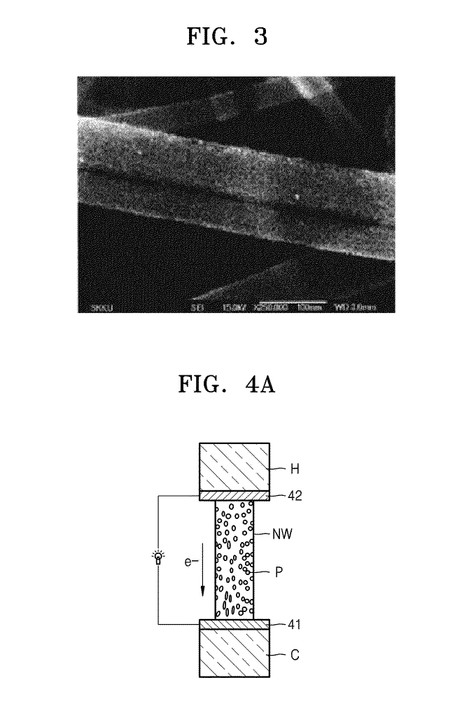

FIG. 3 is a scanning electron microscopic (SEM) image of a nanowire with an uneven surface structure formed on the surface of the shell region. Referring to FIG. 3, fine uneven surface structures formed on the surface of the nanowire may be seen. Sizes and density of the uneven surface structure formed on the surface of the nanowire may be easily controlled by varying the material for forming the uneven surface structure and by varying the processing time.

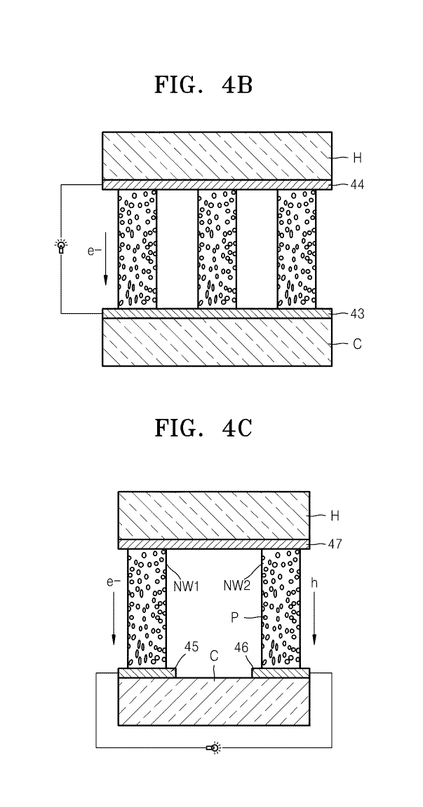

FIGS. 4A through 4C are diagrams showing a thermoelectric device employing a core-shell nanowire with an uneven surface structure.

A thermoelectric device is a device for performing thermoelectric conversion, where the term ‘thermoelectric conversion’ refers to energy conversion between thermal energy and electric energy. When there is a temperature difference between two opposite ends of a thermoelectric material, electricity is generated. This phenomenon is referred to as the Seebeck effect. On the contrary, when a current is applied to the thermoelectric material, a temperature gradient occurs between the two opposite ends of the thermoelectric material and the temperature of the thermoelectric material drops.

This phenomenon is referred to as the Peltier effect. Performance of a thermoelectric device is determined by an efficiency coefficient of a thermoelectric material, that is, a figure of merit—a (ZT) coefficient. The ZT coefficient (non-dimensional) may be expressed as shown below.

$$ZT = \frac{{S}^{2} σ}{k} T \qquad [ Equation 1 ]$$

Here, the ZT coefficient is proportional to the Seebeck coefficient S and electric conductivity σ of a thermoelectric material and is inversely proportional to thermal conductivity k of the thermoelectric material. The Seebeck coefficient S indicates the voltage generated per unit temperature variation (dV/dT). The Seebeck coefficient S, the electric conductivity σ, and the thermal conductivity k are not independent variables and are mutually dependent on each other. Therefore, it is not easy to embody a thermoelectric device exhibiting a high ZT coefficient when the thermoelectric device exhibits high performance.

Referring to FIG. 4A, a nanowire NW having an uneven surface structure P is formed between a first region C and a second region H. Here, temperatures of the first region C and the second region H may be different from each other, and the temperature of the first region C may be lower than the temperature of the second region H. The nanowire NW has a core-shell structure, the uneven surface structure P may be either pore regions which are sunken deeper toward the core region as compared to the remaining regions of the surface of the shell region. In another embodiment, the uneven surface structure P may comprise one or more protruding regions as compared to the remaining regions of the surface of the shell region. Electrodes 41 and 42 may be formed between the nanowire NW and the first region C and between the nanowire NW and the second region H, respectively. The electrodes 41 and 42 may be connected to an electricity condenser for storing electricity generated by the nanowire NW or a load for consuming the electricity generated by the nanowire NW. FIG. 4B is a diagram showing that a plurality of the nanowires NW with the uneven surface structure P are formed between the first region C and the second region H. Common electrodes 43 and 44 may be formed between the nanowires NW and the first region C and between the nanowires NW and the second region H, respectively, where the common electrodes 43 and 44 may be connected to an electricity condenser for storing electricity generated by the nanowires NW or a load for consuming the electricity generated by the nanowires NW.

Referring to FIG. 4C, nanowires NW1 and NW2 with the uneven surface structure P are formed between the first region C and the second region H. Independent electrodes 45 and 46 may be formed between the nanowires NW1 and NW2 and the first region C, whereas a common electrode 47 may be formed between the nanowires NW1 and NW2 and the second region H. Alternatively, independent electrodes may be formed between the nanowires NW1 and NW2 and the second region H, and a common electrode may be formed between the nanowires NW1 and NW2 and the first region C (not shown). The independent electrodes 45 and 46 may be connected to an electricity condenser for storing electricity generated by the nanowires NW1 and NW2 or a load for consuming the electricity generated by the nanowires NW1 and NW2.

If the nanowires NW, NW1, and NW2 are adjacent to the first region C and the second region H where the temperatures are different from each other, electricity may be generated by the nanowires NW, NW1, and NW2 due to a thermoelectric effect. For example, electrons e- may flow in the nanowires NW and NW1 of FIGS. 4A, 4B, and 4C, whereas holes h may flow in the nanowire NW2 of FIG. 4C.

Here, electrons and holes may flow mainly through the core regions of the nanowires NW, NW1, and NW2. If the core regions are doped with an impurity (e.g. a n-type impurity or p-type impurity), conductivity of the core regions may be significantly increased, and thus the electric conductivity a of the nanowires NW, NW1, and NW2 may increase. Furthermore, the uneven surface structure P may scatter phonons in the nanowires NW, NW1, and NW2. As a result, the thermal conductivity of the nanowires NW, NW1, and NW2 may be reduced. Furthermore, since a nanowire exhibits relatively a high density charge state around the Fermi level as compared to a bulk material, the nanowire may exhibit a higher Seebeck coefficient than that of the bulk material. As a result, the nanowires NW, NW1, and NW2 having the uneven surface structure P may have a relatively high Seebeck coefficient. Thus the configuration depicted in the FIGS. 4A, 4B and 4C may be used to create high performance thermoelectric devices.

Although the case in which the temperatures of the first region C and the second region H are different from each other is described above, if there is no temperature difference between the first region C and the second region H, power may be externally applied to form a temperature difference between the first region C and the second region H. In this case, the thermoelectric device functions as a cooling device. For example, referring to the FIG. 4C, a positive power source is connected to the independent electrode 45, which is connected to the first nanowire NW1, and a negative power source is connected to the independent electrode 46, which is connected to the second nanowire NW2. When power is applied, the temperature of the second region H will decrease due to the thermoelectric effect.

As described above, according to the one or more of the above embodiments of the present invention, a core-shell nanowire may be used in various devices, such as a thermoelectric device, by increasing the surface area of the core-shell nanowire and changing electrical characteristics of the core-shell nanowire by forming pores or protrusions on the surface and the interior of the nanowire.

As described above, a core-shell nanowire with an uneven surface structure may be used in a high performance thermoelectric device, because phonons may be scattered and thermal conductivity may be reduced by the uneven surface structure. Furthermore, since the surface area of the core-shell nanowire may be significantly increased, the core-shell nanowire may be widely used in energy-related fields, such as solar-cells. Furthermore, due to a quantization effect of a porous surface, the core-shell nanowire may be used in a light emitting device or a light receiving device.

It should be understood that the exemplary embodiments described therein should be considered in a descriptive sense only and not for purposes of limitation. Descriptions of features or aspects within each embodiment should typically be considered as available for other similar features or aspects in other embodiments.

What is claimed is:

1. A core-shell nanowire comprising:
a nanowire comprising a core region and a shell region, the shell region having an uneven surface structure.

2. The core-shell nanowire of claim 1, wherein the uneven surface structure comprises a plurality of pores formed on a surface of and inside the shell region, or a plurality of protrusions protruding from the surface of the shell region.

3. The core-shell nanowire of claim 1, wherein the core-region or the shell region is formed of a semiconductor family of group IV, a semiconductor family of group III-V, a semiconductor family of group II-VI, oxide semiconductors, nitride semiconductors, or a group VI family atom and at least one of a group IV family atom and a group V family atom.

4. The core-shell nanowire of claim 1, wherein the core region comprises a p-type impurity or an n-type impurity.

5. A method of fabricating a core-shell nanowires comprising:
disposing nanoparticles on a shell region of a core-shell nanowire; where the core-shell nanowire comprises a core region and a shell region,
forming an oxide material on the surface of the shell region by oxidizing the surface of the shell region; and
forming uneven surface structure by removing the oxide material and the nanoparticles.

6. The method of claim 5, wherein the nanoparticles are formed of a metal exhibiting higher electronegativity as compared to that of a material constituting the shell region.

7. The method of claim 5, wherein the shell region is formed of silicon, and the nanoparticles are formed of silver, gold, platinum, copper, or combinations thereof.

8. The method of claim 5, wherein the shell region is formed of silicon, and the nanowire comprises an uneven surface structure produced by oxidizing a surface of the nanowire by using H₂O₂, K₂Cr₂O₇, or KMnO₄.

9. The method of claim 5, wherein, in the disposing of the nanoparticles to the surface of the shell region, the nanoparticles are formed on the surface of the shell region by dipping the nanowire in a solution in which a metal precursor and a fluoric acid are mixed.

10. The method of claim 5, wherein the disposing of the nanoparticles on the surface of the shell region comprises:
removing an oxide layer from the surface of the shell region; and
disposing nanoparticles on the surface of the shell region, wherein the nanoparticles are formed of a material that forms a compound with a material constituting the shell region.

11. The method of claim 10, wherein the shell region is oxidized through a wet oxidization process using H₂O gas or a dry oxidization process using O₂ gas at a temperature of about 600° C. to about 1,100° C.

12. The method of claim 11, wherein a portion oxidized through the wet oxidization process or the dry oxidization process is removed through an etching process, and the nanoparticles are also removed through the etching process.

13. The method of claim 10, wherein the shell region is formed of silicon, and the nanoparticles form a metal silicide by reacting with the silicon present in the shell region.

14. The method of claim 5, wherein the core-region or the shell region is formed of a semiconductor family of group IV, a semiconductor family of group III-V, a semiconductor family of group II-VI, oxide semiconductors, nitride semiconductors, or a group VI family atom and at least one of a group IV family atom and a group V family atom.

15. The method of claim 5, wherein the core region comprises a p-type impurity or an n-type impurity.

16. A thermoelectric device or a cooling device comprising:
a nanowire with an uneven surface structure, the nanowire comprising a core region and a shell region, wherein the uneven surface structure is formed in the shell region.

17. The thermoelectric device of claim 16, wherein the uneven surface structure comprises a plurality of pores formed on a surface of and inside the shell region, or a plurality of protrusions protruding from the surface of the shell region.

18. The thermoelectric device of claim 16, wherein the core-region or the shell region is formed of a semiconductor family of group IV, a semiconductor family of group III-V, a semiconductor family of group II-VI, oxide semiconductors, nitride semiconductors, or a group VI family atom and at least one of a group IV family atom and a group V family atom.

19. The thermoelectric device of claim 16, wherein the core region comprises a p-type impurity or an n-type impurity.
